(19) United States
(12) Patent Application Publication
(10) Pub. No.: US 2025/0056844 A1
(43) Pub. Date: Feb. 13, 2025

(54) FERROELECTRIC FIELD EFFECT TRANSISTOR, MEMORY DEVICE, AND NEURAL NETWORK APPARATUS INCLUDING GATE-INTERPOSED LAYER

(71) Applicant: Samsung Electronics Co., Ltd., Suwon-si (KR)

(72) Inventors: Hyunjae LEE, Suwon-si (KR); Seunggeol NAM, Suwon-si (KR); Sijung YOO, Suwon-si (KR); Dukhyun CHOE, Suwon-si (KR)

(73) Assignee: Samsung Electronics Co., Ltd., Suwon-si (KR)

(21) Appl. No.: 18/761,631

(22) Filed: Jul. 2, 2024

(30) Foreign Application Priority Data
Aug. 8, 2023 (KR) 10-2023-0103667

(51) Int. Cl. H01L 29/78; H01L 21/28; H01L 29/51; H10B 51/30

(52) U.S. Cl. CPC H01L 29/78391; H01L 29/40111; H01L 29/516; H10B 51/30

(57) ABSTRACT

Provided is a ferroelectric field effect transistor including a source region, a drain region, a channel provided between the source region and the drain region, a ferroelectric layer provided on the channel and including a ferroelectric material including an oxide of a first element, a gate-interposed layer provided on the ferroelectric layer and including a paraelectric material including an oxide of a second element different from the first element, and a gate electrode provided on the gate-interposed layer, wherein the gate-interposed layer includes a first interposed layer adjacent to the ferroelectric layer, and a second interposed layer adjacent to the gate electrode, the first interposed layer includes a mixture of the first element and the second element, and a ratio of the first element in the first interposed layer may be greater than a ratio of the first element in the ferroelectric layer.

### CROSS-REFERENCE TO RELATED APPLICATION

This application is based on and claims priority under 35 U.S.C. § 119 to Korean Patent Application No. 10-2023-0103667, filed on Aug. 8, 2023, in the Korean Intellectual Property Office, the disclosure of which is incorporated by reference herein in its entirety.

### BACKGROUND

### 1. Field

The disclosure relates to a ferroelectric field effect transistor, a memory device, and a neural network apparatus including a gate-interposed layer.

### 2. Description of the Related Art

Ferroelectrics are materials with ferroelectricity (e.g., that maintain spontaneous polarization by aligning internal electric dipole moments without an electric field being applied from an external electric field source). For example, after a voltage at or above a threshold is applied to the ferroelectrics, polarization remains semi-permanent in the ferroelectrics even though the voltage of the ferroelectrics is taken back to 0 V. Research on applying these ferroelectric properties in logic devices or memory devices continues. For example, in the case of a ferroelectric field effect transistor using ferroelectrics, the threshold voltage of the field effect transistor may vary depending on the polarization direction in the ferroelectrics. Logic devices or memory devices may be implemented using threshold voltage variation characteristics of such ferroelectric field effect transistors.

### SUMMARY

Provided is a ferroelectric field effect transistor including a gate-interposed layer for increasing a memory window which is a difference between two different threshold voltages.

In addition, provided is a memory device including a gate-interposed layer.

In addition, provided is a neural network device that includes a ferroelectric field effect transistor with a gate-interposed layer.

Additional aspects will be set forth in part in the description which follows and, in part, will be apparent from the description, or may be learned by practice of the presented embodiments of the disclosure.

According to an aspect of at least one embodiment, a ferroelectric field effect transistor includes a source region, a drain region, a channel between the source region and the drain region, a gate electrode over the channel, a ferroelectric layer between the gate electrode and the channel and including a ferroelectric material including an oxide of a first element, and a gate-interposed layer between the ferroelectric layer and the gate electrode and including a paraelectric material including an oxide of a second element different from the first element, wherein the gate-interposed layer comprises a first interposed region adjacent to the ferroelectric layer; and a second interposed region adjacent to the gate electrode, and the first interposed region includes a mixture of the first element and the second element, and an average ratio of the first element in the first interposed region is greater than an average ratio of the first element in the ferroelectric layer.

The paraelectric material may have a dielectric constant of, for example, about 8 or less.

The paraelectric material may include, for example, at least one of SiO₂, Al₂O₃, SiAlOₓ, or Si₃N₄.

The first interposed layer may be configured as a charge trap.

A content of the first element in the ferroelectric layer and the first interposed region may exhibit a first peak in the ferroelectric layer, and a second peak in the first interposed region, and may decrease with proximity towards the second interposed region.

A magnitude of the second peak may be greater than a magnitude of the first peak.

The magnitude of the second peak may be, for example, about 105% or more of the magnitude of the first peak.

The first element may include, for example, at least one of hafnium (Hf) or zirconium (Zr).

The first element is hafnium (Hf), and the difference between the element content of hafnium in the first interposed region and the element content of hafnium in the ferroelectric layer may be, for example, greater than about 0 at % but less than or equal to about 25 at %.

The first element is hafnium (Hf), and the element content of hafnium in the first interposed region may be, for example, within a range of about 105% to about 130% of the element content of hafnium in the ferroelectric layer.

The content of the second element in the first interposed region gradually may increase, and the content of the second element in the second interposed region may represent a peak.

For example, the thickness of the first interposed region may be within a range of about 1 nm to about 7 nm, the thickness of the second interposed region may be within a range of about 3 nm or more, and the thickness of the gate-interposed layer may be within a range of about 4 nm to about 10 nm.

The ferroelectric layer may include a plurality of first material layers and at least one second material layer provided between two adjacent first material layers facing each other, the first material layer may include the ferroelectric material, and the second material layer may include a paraelectric material.

For example, the thickness of the first material layer may be within a range of about 5 nm to about 10 nm, and the thickness of the second material layer may be within a range of about 0.1 nm to about 1 nm.

For example, the paraelectric material of the second material layer may include at least one of Al₂O₃, SiO₂, La₂O₃, or Y₂O₃.

The ferroelectric field effect transistor may further include an interfacial layer between the channel and the ferroelectric layer, wherein the interfacial layer may include an oxide of a semiconductor material or an oxynitride of a semiconductor material.

The ferroelectric field effect transistor may further include a diffusion barrier layer between the ferroelectric layer and the interfacial layer, wherein the diffusion barrier layer may include, for example, at least one of SiN, AlN, or TaN.

The thickness of the diffusion barrier layer may be, for example, within a range of about 1 nm to about 2 nm.

According to another aspect of an embodiment, a memory device includes a plurality of gate electrodes and a plurality of spacers alternating in a first direction, a channel extending in the first direction and spaced apart from the plurality of gate electrodes and the plurality of spacers in a second direction perpendicular to the first direction, a ferroelectric layer extending in the first direction and between the channel and the plurality of gate electrodes, the ferroelectric layer including a ferroelectric material including an oxide of a first element, and a gate-interposed layer extending in the first direction, provided between the ferroelectric layer and the plurality of gate electrodes, and including a paraelectric material including an oxide of a second element different from the first element, wherein the gate-interposed layer includes a first interposed region adjacent to the ferroelectric layer, and a second interposed region adjacent to the gate electrode, the first interposed region includes a mixture of the first element and the second element, and an average ratio of the first element in the first interposed region may be greater than an average ratio of the first element in the ferroelectric layer.

According to another aspect of an embodiment, a neural network apparatus includes an array of a plurality of synapse elements that are two-dimensionally provided, wherein each of the synapse elements includes an access transistor and a ferroelectric field effect transistor, and the ferroelectric field effect transistor includes a source region, a drain region, a channel between the source region and the drain region, a gate electrode over the channel, a ferroelectric layer between the gate electrode and the channel and including a ferroelectric material including an oxide of a first element, and a gate-interposed layer between the ferroelectric layer and the gate electrode and including a paraelectric material including an oxide of a second element different from the first element, wherein the gate-interposed layer comprises a first interposed region adjacent to the ferroelectric layer; and a second interposed region adjacent to the gate electrode, and the first interposed region includes a mixture of the first element and the second element, and an average ratio of the first element in the first interposed region is greater than an average ratio of the first element in the ferroelectric layer

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically showing the structure of a ferroelectric field effect transistor according to at least one embodiment;

FIG. 2 is a graph showing an example of a trap concentration distribution in a gate-interposed layer in a ferroelectric field effect transistor according to the at least one embodiment shown in FIG. 1;

FIG. 3A is a conceptual view of charge distribution in a ferroelectric field effect transistor according to at least one embodiment in a program state, and FIG. 3B is a conceptual view of charge density in a ferroelectric field effect transistor according to at least one embodiment in a program state;

FIG. 4A is a conceptual view of charge distribution in a ferroelectric field effect transistor according to at least one embodiment in an erase state, and FIG. 4B is a conceptual view of charge density in a ferroelectric field effect transistor according to at least one embodiment in an erase state;

FIG. 5 is a cross-sectional view schematically showing a structure of a ferroelectric field effect transistor according to at least one embodiment;

FIG. 6 is a graph showing an example of a trap concentration distribution in a gate-interposed layer in a ferroelectric field effect transistor according to the at least one embodiment shown in FIG. 5;

FIG. 7 is a cross-sectional view schematically showing a structure of a ferroelectric field effect transistor according to at least one embodiment;

FIG. 8 is a cross-sectional view schematically showing a structure of a ferroelectric field effect transistor according to at least one embodiment;

FIG. 9 is a cross-sectional view schematically showing a structure of a ferroelectric field effect transistor according to at least one embodiment;

FIG. 10 is a cross-sectional view schematically illustrating a structure of a memory cell string of a memory device according to at least one embodiment;

FIGS. 11A and 11B are cross-sectional views schematically showing a method of manufacturing a memory cell string of the memory device shown in FIG. 10;

FIGS. 12A to 12C are cross-sectional views schematically showing another method of manufacturing a memory cell string of the memory device shown in FIG. 10;

FIG. 13 is a cross-sectional view schematically illustrating a structure of a memory cell string of a memory device according to at least one embodiment;

FIG. 14 is a cross-sectional view schematically illustrating a structure of a memory cell string of a memory device according to at least one embodiment;

FIG. 15 is a schematic circuit diagram of a neural network apparatus according to at least one embodiment; and

FIG. 16 is a schematic block diagram showing an example configuration of an electronic apparatus including a neural network apparatus.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a ferroelectric field effect transistor, a memory device, and a neural network apparatus including a gate-interposed layer will be described in detail with reference to the accompanying drawings. In the following drawings, like reference numerals refer to like components and elements, and the size of each component in the drawings may be exaggerated for clarity and convenience of description. In addition, the embodiments described below are merely exemplary and various modifications are possible from these embodiments.

Hereinafter, the term “upper portion” or “on” may also include “to be present on a non-contact basis” as well as “to be in directly contact with”. The singular expression includes multiple expressions unless the context clearly implies otherwise. In addition, when a part “includes” a component, this means that it may further include other components, not excluding other components unless otherwise opposed. Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly.

The use of the term “the” and similar indicative terms may correspond to both singular and plural. If there is no explicit description of an order for steps that make up a method or vice versa, these steps can be done in an appropriate order and are not necessarily limited to the order described.

Further, the terms “processor”, “unit”, “module”, or the like represents units that processes at least one function or operation, which may be implemented in processing circuitry such as hardware, software, and/or implemented in a combination of hardware and software. For example, the processing circuitry more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The connection or connection members of lines between the components shown in the drawings exemplarily represent functional connection and/or physical or circuit connections, and may be replaceable or represented as various additional functional connections, physical connections, or circuit connections in an actual device.

The use of all examples or exemplary terms is simply to describe technical ideas in detail, and the scope is not limited by these examples or exemplary terms unless the scope is limited by the claims. Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

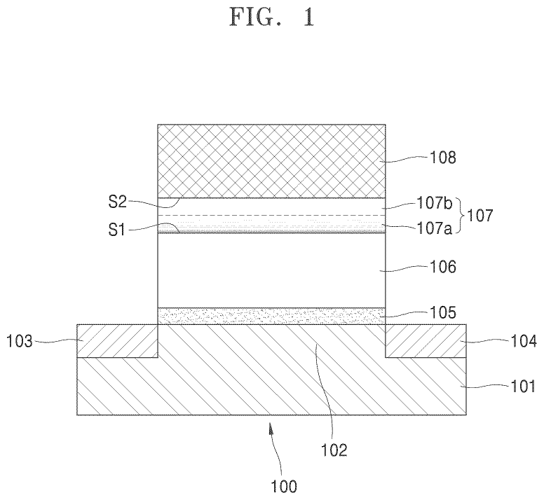

FIG. 1 is a cross-sectional view schematically showing the structure of a ferroelectric field effect transistor according to at least one embodiment. Referring to FIG. 1, a ferroelectric field effect transistor 100 according to at least one embodiment may include a source region 103, a drain region 104, a channel 102 provided between the source region 103 and the drain region 104, a ferroelectric layer 106 provided on an upper surface of the channel 102, a gate-interposed layer 107 provided on an upper surface of the ferroelectric layer 106, and a gate electrode 108 provided on an upper surface of the gate-interposed layer 107.

In addition, the ferroelectric field effect transistor 100 may further include an interfacial layer 105 provided between the channel 102 and the ferroelectric layer 106. The ferroelectric field effect transistor 100 may further include a substrate 101. In at least some embodiments, the source region 103 and the drain region 104 may be provided on opposite sides of an upper portion of the substrate 101. The channel 102 may be a partial region of the upper portion of the substrate 101.

However, the example embodiments are not limited thereto. For example, in at least one embodiment, the channel 102, the source region 103, and/or the drain region 104 may be formed separately from and transferred to the substrate 101. Although not shown, the ferroelectric field effect transistor 100 may further include a source electrode and a drain electrode provided above the source region 103 and the drain region 104, respectively.

The source region 103 and the drain region 104 may be doped with a first conductance type, and the substrate 101 may be doped with a second conductance type electrically opposed to the first conductance type. For example, the substrate 101 may include a p-type semiconductor, the source region 103 and the drain region 104 may include an n-type semiconductor, or the substrate 101 may include an n-type semiconductor, and the source region 103 and the drain region 104 may include a p-type semiconductor. In at least some embodiments, the substrate 101 may be doped at a relatively low concentration of about 10¹⁶ to 10¹⁷/cm³, while the source region 103 and the drain region 104 may be doped at a relatively high concentration of about 10¹⁹ to 10²¹/cm³ for low resistance. The source region 103 and the drain region 104 may be formed by doping both sides of the upper portion of the substrate 101, respectively. The upper region of the substrate 101 where the source region 103 and the drain region 104 are not formed becomes the channel 102.

Accordingly, the channel 102 may be provided between the source region 103 and the drain region 104.

The substrate 101, the channel 102, the source region 103, and the drain region 104 may include at least one semiconductor material. For example, the at least one semiconductor material may include at least one of a group IV semiconductor (such as silicon (Si), germanium (Ge), and SiGe), a group III-V compound semiconductor (such as GaAs and GaP), a group II-VI compound semiconductors, oxide semiconductors, two-dimensional material semiconductors, and/or the like. When the substrate 101, the channel 102, the source region 103, and the drain region 104 include Si, Ge, SiGe, etc., the substrate 101 and the channel 102 may be doped with at least one dopant of B, Al, Ga, and In, and the source region 103 and the drain region 104 may be doped with at least one dopant of P, As, and Sb. Then, the ferroelectric field effect transistor 100 becomes an n-channel metal oxide semiconductor (NMOS) field effect transistor. Alternatively, the substrate 101 and the channel 102 may be doped with at least one dopant of P, As, and Sb, and the source region 142 and the drain region 143 may be doped with at least one dopant of B, Al, Ga, and In. In this case, the ferroelectric field effect transistor 100 is a p-channel metal oxide semiconductor (PMOS) field effect transistor.

The ferroelectric layer 106 may include a ferroelectric material (also referred to as a ferroelectric). The threshold voltage of the semiconductor device 100 may change depending on a polarization direction of the ferroelectric layer 106, for example, a direction from the gate electrode 108 to the channel 104, or vice versa.

The ferroelectric layer 106 may include, for example, a ferroelectric having at least one of a fluorite structure, a perovskite structure, and a wurtzite structure. The ferroelectric having a fluoride structure may include, for example, hafnium oxide (HfO₂). For example, the hafnium oxide may be doped with at least one element of zirconium (Zr), lanthanum (La), aluminum (Al), silicon (Si), yttrium (Y), and gadolinium (Gd). In at least one embodiment, the ferroelectric layer 106 may include an antiferroelectric material. For example, the antiferroelectric material may include zirconium oxide. For example, the zirconium oxide may be doped with at least one element of hafnium (Hf), lanthanum (La), aluminum (Al), silicon (Si), yttrium (Y), and gadolinium (Gd). In addition, the ferroelectric having a perovskite structure may include, for example, lead zirconate titanate (PZT). The ferroelectric having a wurtzite structure may include, for example, zinc oxide (ZnO) or aluminum nitride (AlN). The ferroelectric of such a wurtzite structure may be doped with, for example, at least one element of boron (B) and scandium (Sc). In addition, the ferroelectric layer 106 may include the antiferroelectric material as well as the ferroelectric material described above. For example, the antiferroelectric material may include ZrO₂.

The ferroelectric layer 106 may include at least one of hafnium (Hf) and zirconium (Zr). The ferroelectric layer 106 may include hafnium and zirconium in substantially the same element ratio (e.g., Hf_{0.5}Zr_{0.5}O₂), and additionally, at least one element among lanthanum (La), aluminum (Al), silicon (Si), yttrium (Y), and gadolinium (Gd) may be doped at a ratio of less than about 10 at %.

The thickness of the ferroelectric layer 106 may be, for example, about 5 nm to about 20 nm.

The interfacial layer 105 may be formed by naturally oxidizing the semiconductor material of the channel 102 in the process of manufacturing the ferroelectric field effect transistor 100. Thus, the interfacial layer 105 may include an oxide of a semiconductor material. For example, when the channel 102 includes Si, Ge, SiGe, etc., the interfacial layer 105 may include a respective SiO₂, GeO₂, SiGeO₄, etc. In addition, the interfacial layer 105 may be nitrided to lower the concentration of the charge trap in the interfacial layer 105 and increase the dielectric constant of the interfacial layer 105. In these cases, the interfacial layer 105 may include an oxynitride of a semiconductor material. For example, the interfacial layer 105 may include SiON, GeON, SiGeOₓN_{y}, etc. When the interfacial layer 105 has a relatively high dielectric constant, a voltage applied to the interfacial layer 105 may be lowered and a voltage applied to the ferroelectric layer 106 may be increased.

The thickness of the interfacial layer 105 may be about 2 nm to about 5 nm.

The gate electrode 108 may have conductance of approximately 1 Mohm/square or less. The gate electrode 108 may include one or more electrically conductive materials, such as at least one material selected from the group consisting of metals, metal nitrides, metal carbides, polysilicon, combinations thereof, and/or the like. For example, the metals may include aluminum (Al), tungsten (W), molybdenum (Mo), titanium (Ti), tantalum (Ta), and/or the like; the metal nitrides may include titanium nitride (TiN), tantalum nitride (TaN), and/or the like; and the metal carbides may include aluminum, silicon doped (or containing) metal carbides and/or the like (for example, TiAlC, TaAlC, TiSiC, or TaSiC). The gate electrode 108 may have a structure in which a plurality of materials are stacked. For example, the gate electrode 108 may have a laminated structure of a metal nitride layer/metal layer such as TiN/Al or a laminated structure of a metal nitride layer/metal carbide layer/metal layer such as TiN/TiAlC/W. The gate electrode 108 may include a titanium nitride (TiN) layer or molybdenum (Mo), and the example may be used in various modifications. In at least some embodiments, the gate electrode 108 may include a conductive two-dimensional material in addition to the materials described above. For example, the conductive two-dimensional material may include at least one of graphene, black phosphorus, amorphous boron nitride, two-dimensional hexagonal boron nitride (h-BN), phosphorene, and/or the like.

The gate-interposed layer 107 provided between the ferroelectric layer 106 and the gate electrode 108 is a layer provided to increase the memory window of the ferroelectric field effect transistor 100. The memory window is a difference between two different threshold voltages of the ferroelectric field effect transistor 100. As the memory window increases, the operational reliability of the ferroelectric field effect transistor 100 may be improved. For example, the memory window of the ferroelectric field effect transistor 100 may be about 6.5 V or more.

To increase the memory window of the ferroelectric field effect transistor 100, the gate-interposed layer 107 may be configured to lower the overall capacitance between the gate electrode 108 and the ferroelectric layer 106. To this end, the gate-interposed layer 107 may include a charge trap configured to hold sufficient charges to offset the polarization of the ferroelectric layer 106 at the interface S1 with the ferroelectric layer 106. The gate-interposed layer 107 may include a paraelectric of a low dielectric constant at the interface S2 with the gate electrode 108 to prevent (and/or mitigate) charges trapped in the charge trap from escaping through the gate electrode 108.

In at least one embodiment, the gate-interposed layer 107 may include a first interposed layer (or a first interposed region) 107a adjacent to the upper surface of the ferroelectric layer 106 and a second interposed layer (or a second interposed region) 107b adjacent to the lower surface of the gate electrode 108. The first interposed layer 107a may be provided between the ferroelectric layer 106 and the second interposed layer 107b, and the second interposed layer 107b may be provided between the first interposed layer 107a and the gate electrode 108. The second interposed layer 107b may include a pure paraelectric material having a low dielectric constant. The second interposed layer 107b may include, for example, a paraelectric material having a dielectric constant of about 8 or less. For example, the paraelectric material may include at least one of SiO₂, Al₂O₃, SiAlOₓ, and Si₃N₄. In addition, the first interposed layer 107a may include a mixture of the paraelectric material of the second interposed layer 107b and the material of the ferroelectric layer 106. As such, a charge trap formed by a mixture of a paraelectric material of the second interposed layer 107b and a material of the ferroelectric layer 106 may exist in the first interposed layer 107a.

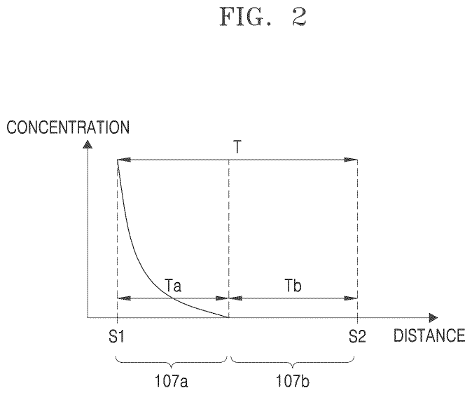

FIG. 2 is a graph showing an example of a trap concentration distribution in a gate-interposed layer 107 in a ferroelectric field effect transistor 100 according to the at least one embodiment shown in FIG. 1. Referring to FIG. 2, the trap concentration in the gate-interposed layer 107 may gradually decrease from the interface Si with the ferroelectric layer 106, and the trap concentration may be completely zero at a predetermined location inside the gate-interposed layer 107. The predetermined position of the trap within the gate-interposed layer 107 can be calculated, for example, through a first principle calculation method (e.g., ab initio quantum chemistry methods). In addition, the amount of traps in the gate-interposed layer 107 may be measured indirectly by measuring capacitance at the trap location. A region in which a charge trap exists in the gate-interposed layer 107 may be referred to as a first interposed layer 107a, and a region in which the charge trap is not present may be referred to as a second interposed layer 107b. The trap concentration in the first interposed layer 107a may gradually decrease from the interface S1 with the ferroelectric layer 106 to the second interposed layer 107b, and the trap concentration in the second interposed layer 107b may become zero. The thickness Ta of the first interposed layer 107a may be, for example, about 1 nm or more and about 7 nm or less. The thickness Tb of the second interposed layer 107b may be about 3 nm or more to sufficiently prevent leakage of charges trapped in the trap. The total thickness T of the gate-interposed layer 107 may be, for example, about 4 nm or more and about 10 nm or less.

The trap concentration gradient of the first interposed layer 107a shown in FIG. 2 is due to the concentration gradient of the material of the ferroelectric layer 106 and the concentration gradient of the paraelectric material within the gate-interposed layer 107, especially within the first interposed layer 107a. In at least one embodiment, the concentration of the material of the ferroelectric layer 106 in the first interposed layer 107a may gradually decrease as it approaches the gate electrode 108, especially the second interposed layer 107b, and the concentration of the paraelectric material may gradually increase closer to the gate electrode 108. Then, the gradient of the trap concentration shown in FIG. 2 may be obtained.

The charge traps in the first interposed layer 107a may be formed of a ferroelectric material distributed in the first interposed layer 107a. For example, a charge trap may be present within the first interposed layer 107a due to a high ratio of the ferroelectric material (e.g., Hf) within the first interposed layer 107a. In addition, as the content of ferroelectric material (e.g., Hf) decreases closer to the second interposed layer 107b, a trap concentration gradient as shown in FIG. 2 may appear. After forming the ferroelectric layer 106 and the gate-interposed layer 107, the compositions and thicknesses of the materials in the ferroelectric layer 106 and the gate-interposed layer 107 may be measured, for example, by secondary ion mass spectrometry (SIMS). The ferroelectric layer 106 may use hafnium oxide (HfO₂) doped with zirconium (Zr), and the gate-interposed layer 107 may use silicon oxide (SiO₂). In these cases, a SIMS results shows that the ferroelectric layer 106 includes a ferroelectric material including an oxide of a first element, the gate-interposed layer 107 includes a paraelectric material including an oxide of a second element different from the first element, and the ferroelectric layer 106 may be doped with a third element different from the first element or further includes an oxide of the third element. Here, the first element may be hafnium (Hf), the second element may be silicon (Si), and the third element may be zirconium (Zr).

First, looking at the distribution of silicon (Si), silicon does not exist inside the ferroelectric layer 106, and the content of silicon may gradually increase toward the gate electrode 108 within the gate-interposed layer 107. In particular, the content of silicon gradually increases in the first interposed layer 107a, and a content peak of silicon may appear in the second interposed layer 107b.

In the case of hafnium (Hf), a local peak (e.g., a first peak) of the hafnium content appears near the center of the ferroelectric layer 106, and the content of hafnium may gradually decrease towards the boundary between the ferroelectric layer 106 and the gate-interposed layer 107. In addition, after the content of hafnium in the gate-interposed layer 107 increases smoothly, the content of hafnium may decrease rapidly again. In particular, after a peak (e.g., a second peak) of the hafnium content appears in the first interposed layer 107a, the hafnium content may decrease rapidly closer to the second interposed layer 107b, and hafnium may hardly exist inside the second interposed layer 107b. The content peak (e.g., the second peak) of hafnium in the first interposed layer 107a may be greater than the content peak (e.g., the first peak) of hafnium in the ferroelectric layer 106. The content peak (e.g., the second peak) of hafnium in the first interposed layer 107a may be about 105% to about 120% of the content peak (e.g., the first peak) of hafnium in the ferroelectric layer 106.

In addition, looking at the distribution of zirconium (Zr), zirconium forms nearly 1:1 with respect to hafnium in the lower portion of the ferroelectric layer 106 (e.g., in the region adjacent to the channel 102), and may increase more slightly than hafnium in the region adjacent to the gate-interposed layer 107. In addition, the content of zirconium may be drastically reduced within the gate-interposed layer 107, especially within the first interposed layer 107a.

The average ratio of hafnium (or the element content of hafnium) in the first interposed layer 107a may be greater than the average ratio of hafnium (or the element content of hafnium) in the ferroelectric layer 106. The difference between the average ratio of hafnium (or the element content of hafnium) in the ferroelectric layer 106 and the average ratio of hafnium (or the element content of hafnium) in the first interposed layer 107a may be greater than approximately 0 at % and less than or equal to about 25 at %. For example, the difference between the average ratio of hafnium (or the element content of hafnium) in the ferroelectric layer 106 and the average ratio of hafnium (or the element content of hafnium) in the first interposed layer 107a may be about 2 at % or more, or about 3 at % or more, and about 20 at % or less, or about 15 at % or less. In addition, the average ratio of hafnium (or the element content of hafnium) inside the first interposed layer 107a may be about 130% or less of the average ratio of hafnium (or the element content of hafnium) inside the ferroelectric layer 106. For example, the average ratio of hafnium (or the element content of hafnium) inside the first interposed layer 107a may be about 105% or more and/or about 107% or more, but may be about 125% or less of the average ratio of hafnium (or the element content of hafnium) inside the ferroelectric layer 106.

For example, the element content of hafnium in the ferroelectric layer 106 may be up to about 75 at %. The element content of hafnium in the ferroelectric layer 106 may be about 40 at % to about 50 at %, and the element content of hafnium in the first interposed layer 107a may be about 55 at % to about 65 at %. The element content of hafnium may be a ratio of the element content to the total amount of metal/non-metal elements forming the ferroelectric layer 106 or the first interposed layer 107a. For example, when the ferroelectric layer 106 is made of hafnium oxide and zirconium oxide, the element content of hafnium in the ferroelectric layer 106 may be represented by an element content ratio of Hf/(Hf+Zr) except for an oxygen ratio. In addition, when the first interposed layer 107a is composed of hafnium oxide, zirconium oxide, and silicon oxide, the element content of hafnium in the ferroelectric layer 106 may be represented as an element content ratio of Hf/(Hf+Zr+Si).

The specific values illustrated may vary depending on various compositions in the ferroelectric layer 106 and the gate-interposed layer 107.

In the above description, the relative ratios of Hf, Zr, and Si in the ferroelectric layer 106 and the gate-interposed layer 107 have been mainly described, but other materials may be included (e.g., instead of Hf, Zr, and Si) depending on the main material of the ferroelectric layer 106 and the main material of the gate-interposed layer 107. For example, when the gate-interposed layer 107 includes Al₂O₃ instead of SiO₂, the relative ratios of Hf, Zr, and Al may change. Even in these cases, the tendency that the average ratio (or element content) of some of the main materials of the ferroelectric layer 106 is greater within the gate-interposed layer 107, especially the first interposed layer 107a, than within the ferroelectric layer 106 may be applied equally. In addition, although it has been described that the element content of hafnium (Hf) in the ferroelectric layer 106 changes, the element content of zirconium (Zr) may be changed instead of and/or in addition to hafnium (Hf). In other words, the first element may be zirconium (Zr) and the third element may be hafnium (Hf). In addition, other ferroelectric materials in addition to hafnium (Hf) and zirconium (Zr) may be selected as the first or third element.

The first interposed layer 107a including the ferroelectric material may be formed in two ways. For example, after depositing only the paraelectric material to a sufficient thickness over the ferroelectric layer 106, heat treatment may be performed at a temperature of about 700° C. to about 900° C. to diffuse the materials of the ferroelectric layer 106 to the paraelectric material. Then, a portion of the paraelectric material on the ferroelectric layer 106, which is in contact with the ferroelectric layer 106, may be the first interposed layer 107a including a material of the ferroelectric layer 106. Among the paraelectric materials on the ferroelectric layer 106, the region where the material of the ferroelectric layer 106 is not diffused may be the second interposed layer 107b. Alternatively, instead of diffusion through heat treatment, for example, it is possible to sequentially form a first interposed layer 107a with a trap concentration gradient and a second interposed layer 107b containing only a paraelectric material by intentionally gradually adjusting the ratio of the ferroelectric layer 106 and the paraelectric material by a deposition method such as an atomic layer deposition (ALD) method.

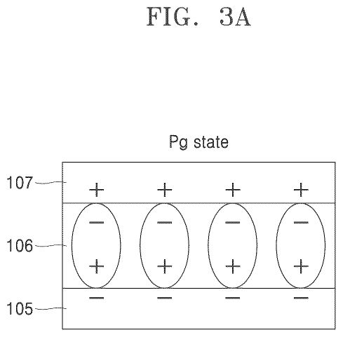

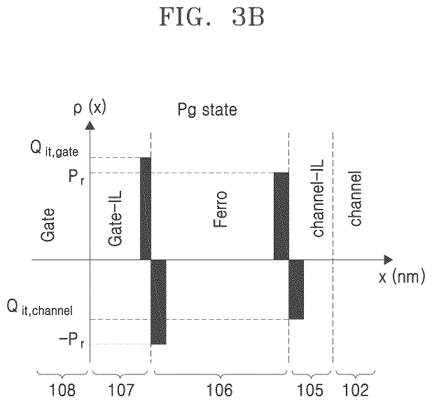

FIG. 3A is a conceptual view of a charge distribution in a ferroelectric field effect transistor 100 in a program state according to at least one embodiment, and FIG. 3B is a conceptual view of a charge density in a ferroelectric field effect transistor 100 in a program state according to at least one embodiment.

Referring to FIG. 3A, in the case of the ferroelectric field effect transistor 100 of an NMOS type, when positive charges in the ferroelectric layer 106 are directed toward the channel 102 and negative charges are directed toward the gate electrode 108, the ferroelectric field effect transistor 100 may be in a program state. In the program state, negative charges may be collected in the interfacial layer 105, and positive charges may be collected in the gate-interposed layer 107. In particular, negative charges may be collected at an interface with the ferroelectric layer 106 in the interfacial layer 105. In addition, positive charges may be collected at an interface with the ferroelectric layer 106 within the first interposed layer 107a of the gate-interposed layer 107. In this program state, electrons may easily flow along the channel 102 and the threshold voltage of the ferroelectric field effect transistor 100 may be lowered.

In the graph of FIG. 3B, the vertical axis represents the charge density, and the horizontal axis represents the locations of the gate electrode 108, the gate-interposed layer 107, the ferroelectric layer 106, the interfacial layer 105, and the channel 102. Referring to FIG. 3B, a charge density Q_{it, gate} of positive charges captured at an interface with the ferroelectric layer 106 in the first interposed layer 107a may be greater than a polarization value Pᵣ of the ferroelectric layer 106. In addition, the charge density Q_{it, channel} of negative charges captured at the interface with the ferroelectric layer 106 within the interfacial layer 105 may be less than the polarization value −Pᵣ of the ferroelectric layer 106.

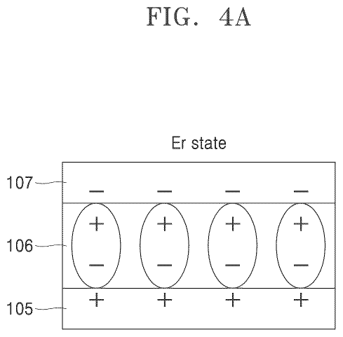

FIG. 4A is a conceptual view of a charge distribution in a ferroelectric field effect transistor 100 in an erase state according to at least one embodiment, and FIG. 4B is a conceptual view of a charge density in a ferroelectric field effect transistor 100 in an erase state according to at least one embodiment.

Referring to FIG. 4A, in the case of the ferroelectric field effect transistor 100 of an NMOS type, when negative charges in the ferroelectric layer 106 are directed toward the channel 102 and positive charges are directed toward the gate electrode 108, the ferroelectric field effect transistor 100 may be in an erase state. The program state and the erase state may be selectively switched by applying a positive coercive voltage or a negative coercive voltage to the gate electrode 108 of the ferroelectric field effect transistor 100. In the erase state, positive charges may be collected in the interfacial layer 105, and negative charges may be collected in the gate-interposed layer 107. In particular, positive charges may be collected at an interface with the ferroelectric layer 106 in the interfacial layer 105. In addition, negative charges may be collected at an interface with the ferroelectric layer 106 within the first interposed layer 107a of the gate-interposed layer 107. In this erase state, electrons may be difficult to flow along the channel 102 and the threshold voltage of the ferroelectric field effect transistor 100 may be heightened.

Referring to FIG. 4B, a charge density of negative charges captured at an interface with the ferroelectric layer 106 in the first interposed layer 107a may be greater than a polarization value of the ferroelectric layer 106. In addition, the charge density of positive charges captured at the interface with the ferroelectric layer 106 within the interfacial layer 105 may be less than the polarization value of the ferroelectric layer 106.

As shown in FIGS. 3B and 4B, the ferroelectric field-effect transistor 100 according to at least one embodiment may include a gate-interposed layer 107 to have a charge trap between the gate electrode 108 and the ferroelectric layer 106 that can hold a charge sufficient to offset the polarization within the ferroelectric layer 106. The charge trap between the gate electrode 108 and the ferroelectric layer 106 increases the memory window of the ferroelectric field effect transistor 100 by reducing the overall capacitance between the gate electrode 108 and the ferroelectric layer 106. In addition, the trap concentration between the ferroelectric layer 106 and the channel 102 may be lower than the trap concentration between the gate electrode 108 and the ferroelectric layer 106 and less than the polarization in the ferroelectric layer 106. Accordingly, the memory window of the ferroelectric field effect transistor 100 may be further increased.

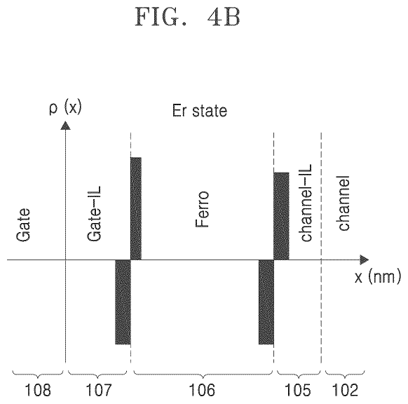

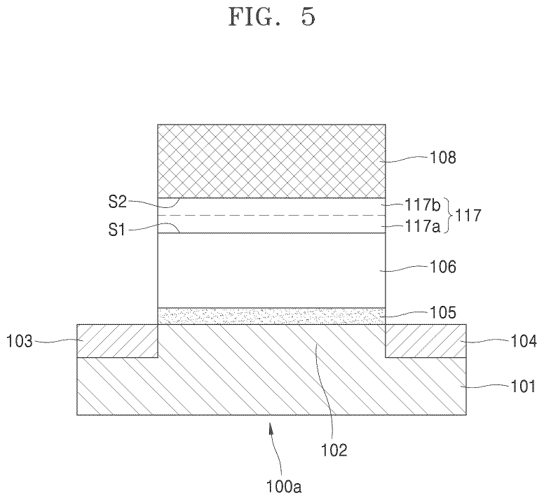

Meanwhile, in FIGS. 3A, 3B, 4A, and 4B, the case where the ferroelectric field effect transistor 100 is an NMOS type has been described, but the same principle may be applied when the ferroelectric field effect transistor 100 is a PMOS type. For example, when the ferroelectric field effect transistor 100 is a PMOS type, the polarity of the electric charges described in FIGS. 3A, 3B, 4A, and 4B may be reversed. FIG. 5 is a cross-sectional view schematically showing a structure of a ferroelectric field effect transistor according to at least one embodiment.

Until now, it has been described that the trap concentration in the first interposed layer 107a gradually changes. However, the gate-interposed layer 117 of the ferroelectric field effect transistor 100a according to at least one embodiment illustrated in FIG. 5 may include a first interposed layer 117a having a constant trap concentration and a second interposed layer 117b including a paraelectric material. The second interposed layer 117b may be the same as the second interposed layer 107b described with reference to FIG. 1.

In addition, the remaining configuration of the ferroelectric field effect transistor 100a shown in FIG. 5 except for the trap concentration of the first interposed layer 117a may be the same as the configuration of the ferroelectric field effect transistor 100 described above.

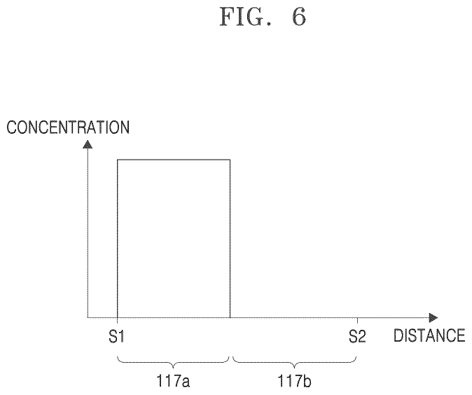

FIG. 6 is a graph showing an example of a trap concentration distribution in a gate-interposed layer 117a in a ferroelectric field effect transistor 100a according to the at least one embodiment shown in FIG. 5. Referring to FIG. 6, a trap concentration may be relatively constant inside the first interposed layer 117a. For example, instead of forming the first interposed layer 117a by diffusing the material of the ferroelectric layer 106, the first interposed layer 117a may be formed by depositing a mixture of the material of the ferroelectric layer 106 and the paraelectric material in a fixed ratio. After the first interposed layer 117a is formed, a second interposed layer 117b may be formed by depositing only a paraelectric material on the upper surface of the first interposed layer 117a.

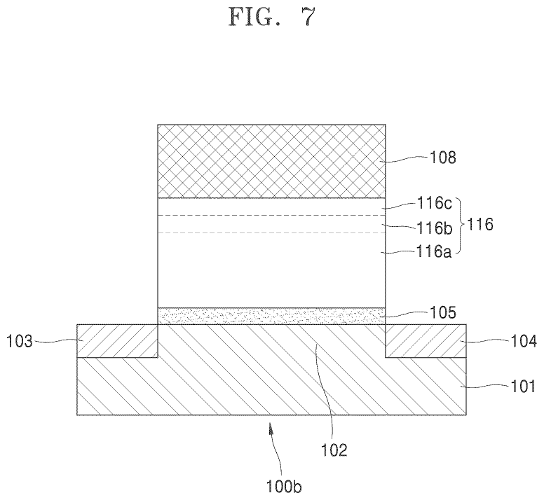

FIG. 7 is a cross-sectional view schematically showing a structure of a ferroelectric field effect transistor according to at least one embodiment. Referring to FIG. 7, the ferroelectric field effect transistor 100b may include one ferroelectric layer 116 between the interfacial layer 105 and the gate electrode 108. In FIG. 1, the boundaries among the ferroelectric layer 106, the first interposed layer 107a, and the second interposed layer 107b is clearly distinguished, but in at least one embodiment, the boundaries among the ferroelectric layer 106, the first interposed layer 107a, and the second interposed layer 107b after manufacturing may not be clearly distinguished. In these cases, the entire parts of the ferroelectric layer 106, the first interposed layer 107a, and the second interposed layer 107b illustrated in FIG. 1 may be regarded as one ferroelectric layer 116, and/or the entire parts of the ferroelectric layer 106, the first interposed layer 107a, and the second interposed layer 107b illustrated in FIG. 1 may be regarded as one gate-interposed layer. Likewise, the boundaries among the ferroelectric layer 106, the first interposed layer 117a, and/or the second interposed layer 117b in FIG. 5 may not be clearly distinguished, and the entire parts of the ferroelectric layer 106, the first interposed layer 117a, and the second interposed layer 117b shown in FIG. 5 may be regarded as one ferroelectric layer 116 or one gate-interposed layer.

The ferroelectric layer 116 may be divided into three regions according to the ratio change of the internal materials. For example, the ferroelectric layer 116 may include a first region 116a on the interfacial layer 105, a second region 116b on the first region 116a, and a third region 116c on the second region 116b. The ferroelectric layer 116 may include, for example, hafnium (Hf), zirconium (Zr), and silicon (Si), and ratios of hafnium (Hf), zirconium (Zr), and silicon (Si) may be different in the first region 116a, the second region 116b, and the third region 116c. For example, while increasing the ratio of hafnium (Hf) from the first region 116a to the second region 116b, a peak of the ratio of hafnium (Hf) may appear in the second region 116b. In addition, the ratio of hafnium (Hf) in the third region 116c may decrease rapidly. The ratio of silicon (Si) is a minimum in the first region 116a, and gradually increases in the second region 116b and the third region 116c, and a peak of the ratio of silicon (Si) in the third region 116c may appear.

In addition, the first region 116a, the second region 116b, and the third region 116c may be distinguished by a ratio of thickness. For example, the thickness of the first region 116a may be about 50% to about 70% of the total thickness of the ferroelectric layer 116. The thickness of the second region 116b may be about 30% to about 50% of the remaining thickness of the ferroelectric layer 116 (e.g., except for the first region 116a). For example, the thickness of the second region 116b may be about 9% to about 25% of the total thickness of the ferroelectric layer 116. The thickness of the third region 116c may be about 15% to about 35% of the total thickness of the ferroelectric layer 116.

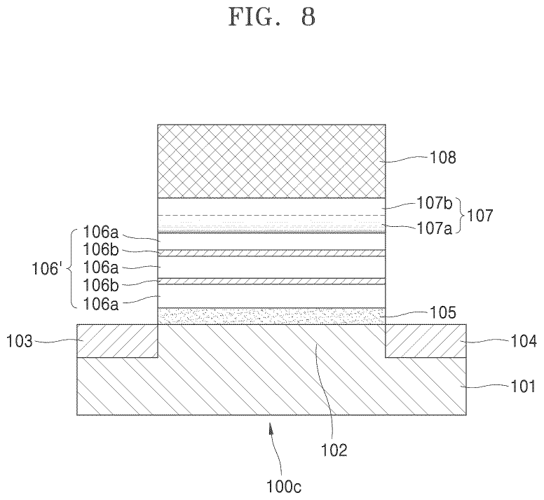

FIG. 8 is a cross-sectional view schematically showing a structure of a ferroelectric field effect transistor according to at least one embodiment. Referring to FIG. 8, a ferroelectric layer 106′ of a ferroelectric field effect transistor 100c according to at least one embodiment may include a plurality of first material layers 106a and at least one second material layer 106b between two adjacent first material layers 106a facing each other. Although three first material layers 106a and two second material layers 106b are illustrated in FIG. 8, the numbers of the first material layers 106a and the second material layers 106b are not limited thereto. For example, the ferroelectric layer 106′ may include two first material layers 106a and one second material layer 106b, the ferroelectric layer 106′ may include four first material layers 106a and three second material layers 106b, and/or the like. The remaining configuration of the ferroelectric field effect transistor 100c shown in FIG. 8 except for the ferroelectric layer 106′ may be the same as the configuration of the ferroelectric field effect transistor 100 described above.

The first material layer 106a may include a ferroelectric material of the ferroelectric layer 106 described with reference to FIG. 1. For example, the first material layer 106a may include a ferroelectric having at least one of the fluorite structure, the perovskite structure, and the wurtzite structure described above. The second material layer 106b may include a paraelectric material. For example, the second material layer 106b may include at least one paraelectric of Al₂O₃, SiO₂, La₂O₃, and Y₂O₃.

In the case of the above-described ferroelectric material, when the thickness is about 10 nm or more, ferroelectric characteristics may gradually deteriorate as the thickness increases. Accordingly, it is difficult to form the ferroelectric layer 106 of FIG. 1 into a single layer having a thickness of about 20 nm or more. As shown in FIG. 8, by stacking the plurality of first material layers 106a including a ferroelectric material, the ferroelectric layer 106′ may be formed to have a thickness of 20 nm or more without degrading ferroelectric properties. The thickness of each of the first material layers 106a may be, for example, about 5 nm to about 10 nm. In addition, the thickness of the second material layer 106b may be small enough not to deteriorate the ferroelectric characteristics of the ferroelectric layer 106′. For example, the thickness of the second material layer 106b may be about 0.1 nm to about 1 nm.

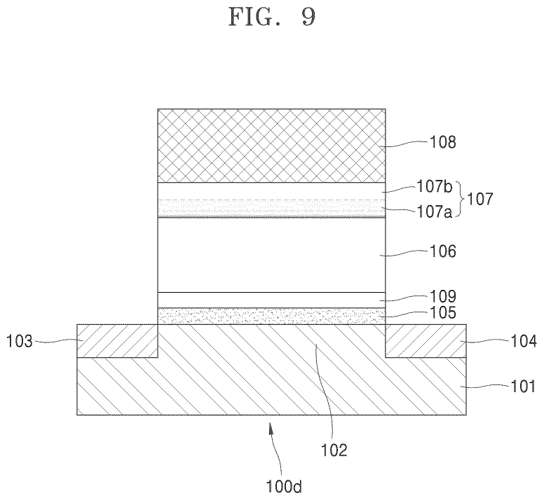

FIG. 9 is a cross-sectional view schematically showing a structure of a ferroelectric field effect transistor according to at least one embodiment. Referring to FIG. 9, the ferroelectric field effect transistor 100d according to at least one embodiment may further include a diffusion barrier layer 109 provided between the ferroelectric layer 106 and the interfacial layer 105. The diffusion barrier layer 109 may be configured to prevent or minimize the diffusion of the ferroelectric material of the ferroelectric layer 106 into the interfacial layer 105 and/or the channel 102. The diffusion barrier layer 109 may include, for example, at least one nitride of SiN, AlN, and TaN. In addition, the thickness of the diffusion barrier layer 109 may be about 1 nm to about 2 nm. The remaining configuration of the ferroelectric field effect transistor 100d shown in FIG. 9 except for the diffusion barrier layer 109 may be the same as the configuration of the ferroelectric field effect transistor 100 described above.

Until now, the ferroelectric field effect transistor having a horizontal planar channel has been described, but the gate-interposed layer 107 described above may also be applied to a memory device having a vertical-negative-AND (VNAND) structure which is a three-dimensional (or vertical) NAND.

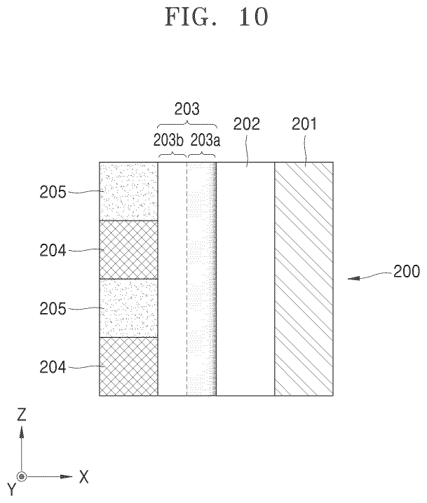

FIG. 10 is a cross-sectional view schematically illustrating a structure of a memory cell string of a memory device, according to at least one embodiment. Referring to FIG. 10, a memory cell string 200 of a memory device according to at least one embodiment may include: a plurality of gate electrodes 204 and a plurality of spacers 205 alternately provided in a first direction (e.g., the Z-axis direction); a channel 201 spaced apart from the plurality of gate electrodes 204 and the plurality of spacers 205 in a second direction (e.g., the X-axis direction) perpendicular to the first direction, and extending in the first direction; a ferroelectric layer 202 extending in the first direction and provided between the channel 201 and the plurality of gate electrodes 204 in the second direction; and a gate-interposed layer 203 extending in the first direction and provided between the ferroelectric layer 202 and the plurality of gate electrodes 204 in the second direction and between the ferroelectric layer 202 and the plurality of spacers 205 in the second direction.

Each of the plurality of spacers 205 may include an insulator (e.g., silicon oxide having insulating properties but is not limited thereto). The ferroelectric layer 202 may include the same ferroelectric material as the ferroelectric layer 106 of FIG. 1.

The gate-interposed layer 203 may include a first interposed layer 203a adjacent to the ferroelectric layer 202, and a second interposed layer 203b adjacent to the plurality of gate electrodes 204 and the plurality of spacers 205. The first interposed layer 203a may be the same as the first interposed layer 107a described with reference to FIG. 1. The second interposed layer 203b may be the same as the second interposed layer 107b described with reference to FIG. 1.

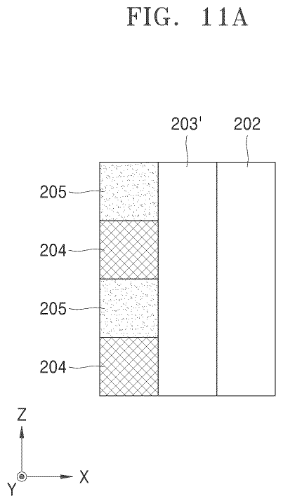

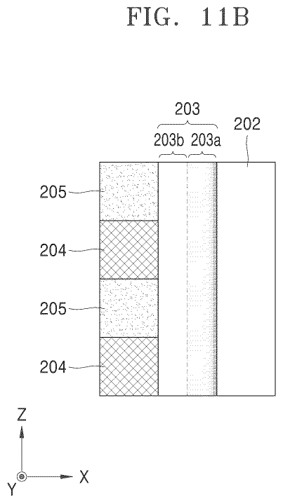

FIGS. 11A and 11B are cross-sectional views schematically showing a method of manufacturing a memory cell string 200 of the memory device shown in FIG. 10.

Referring to FIG. 11A, after the plurality of gate electrodes 204 and the plurality of spacers 205 are stacked, a paraelectric layer 203′ may be conformally deposited on the plurality of gate electrodes 204 and the plurality of spacers 205. In addition, the ferroelectric layer 202 may be conformally deposited along the surface of the paraelectric layer 203′.

Referring to FIG. 11B, by annealing the paraelectric layer 203′ and the ferroelectric layer 202 at a temperature of about 700° C. to about 900° C., materials of the ferroelectric layer 202 may be diffused into the paraelectric layer 203′. Then, some regions of the paraelectric layer 203′ in contact with the ferroelectric layer 202 may become the first interposed layer 203a including the material of the ferroelectric layer 202. A region of the paraelectric layer 203′ where the material of the ferroelectric layer 202 is not diffused may be a second interposed layer 203b. Then, the channel 201 may be conformally deposited along the surface of the ferroelectric layer 202.

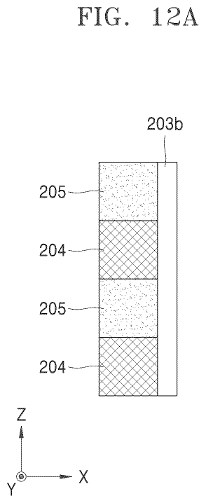

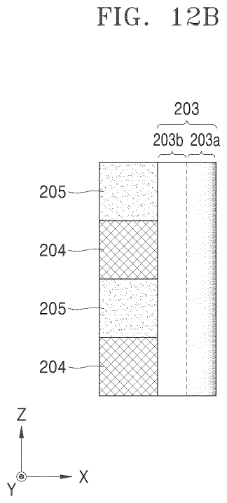

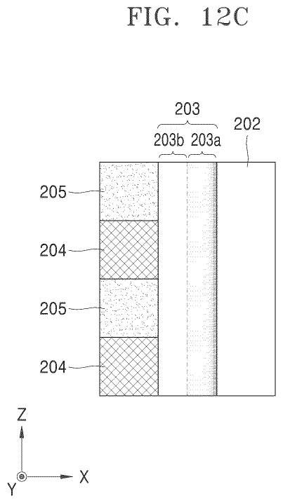

FIGS. 12A to 12C are cross-sectional views schematically showing another method of manufacturing a memory cell string 200 of the memory device shown in FIG. 10.

Referring to FIG. 12A, after the plurality of gate electrodes 204 and the plurality of spacers 205 are stacked, the second interposed layer 203b may be conformally deposited on the plurality of gate electrodes 204 and the plurality of spacers 205.

Referring to FIG. 12B, for example, the first interposed layer 203a may be deposited while gradually adjusting the ratio of the material of the ferroelectric layer 202 and the paraelectric material by an atomic layer deposition (ALD) method. For example, the material of the ferroelectric layer 202 and the paraelectric material may be deposited together while gradually reducing the ratio of the paraelectric material and gradually increasing the material of the ferroelectric layer 202 in atomic layer units.

Referring to FIG. 12C, after forming the gate-interposed layer 203, the ferroelectric layer 202 may be conformally deposited along the surface of the gate-interposed layer 203. Then, the channel 201 may be conformally deposited along the surface of the ferroelectric layer 202.

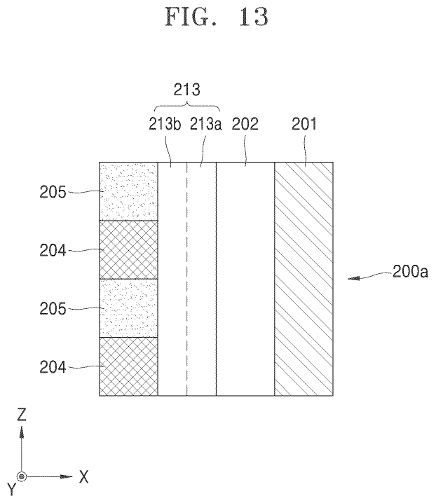

FIG. 13 is a cross-sectional view schematically illustrating a structure of a memory cell string of a memory device, according to at least one embodiment. Referring to FIG. 13, a gate-interposed layer 213 of a memory cell string 200a of a memory device according to at least one embodiment may include a first interposed layer 213a having a constant trap concentration and a second interposed layer 213b including a paraelectric material. The first interposed layer 213a may be the same as the first interposed layer 117a described with reference to FIG. 5 and the second interposed layer 213b may be the same as the second interposed layer 117b described with reference to FIG. 5. In addition, the remaining configuration of the memory cell string 200a of the memory device illustrated in FIG. 13 except for the trap concentration of the first interposed layer 213a may be the same as the configuration of the memory cell string 200 described above.

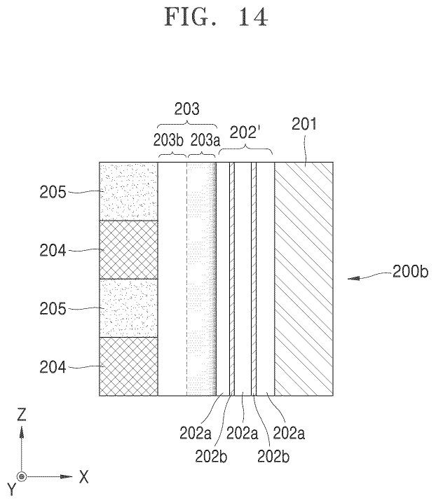

FIG. 14 is a cross-sectional view schematically illustrating a structure of a memory cell string of a memory device, according to at least one embodiment. Referring to FIG. 14, a ferroelectric layer 202′ of a memory cell string 200b of a memory device according to at least one embodiment may include a plurality of first material layers 202a and at least one second material layer 202b placed between two first material layers 202a facing each other in the second direction. Each of the first material layer 202a and the second material layer 202b may extend in the first direction. The first material layer 202a may include the ferroelectric material of the ferroelectric layer 202 described with reference to FIG. 10 and/or the first material layers 106a with reference to FIG. 8. The second material layer 202b may include a paraelectric material, such as the second material layer 106b with reference to FIG. 8.

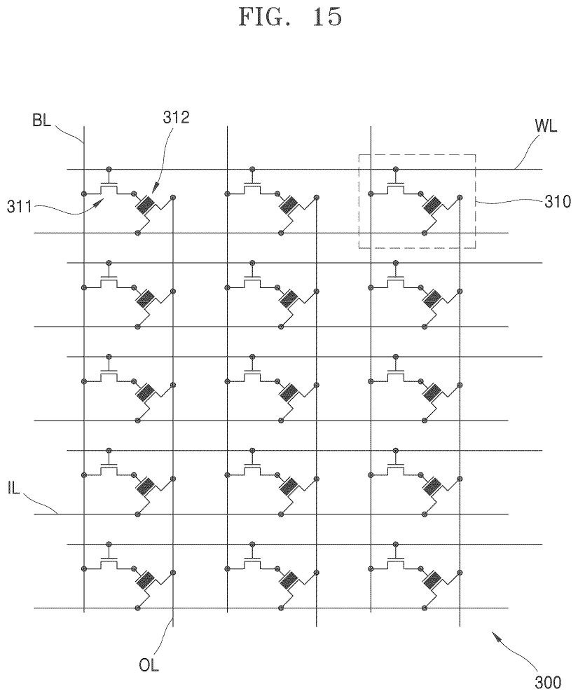

FIG. 15 is a schematic circuit diagram of a neural network apparatus according to at least one embodiment. Referring to FIG. 15, a neural network apparatus 300 according to at least one embodiment may include an array of a plurality of synapse devices 310 provided in two dimensions. Each of the plurality of synapse elements 310 may include an access transistor 311 and a ferroelectric field effect transistor 312. The ferroelectric field effect transistor 312 may be any one of the ferroelectric field effect transistors 100, 100a, 100b, 100c, and 100d described in FIGS. 1 to 9. The access transistor 311 may serve as a selection element for turning on/off the synapse element 550.

The neural network apparatus 300 may also include a plurality of word lines WL, a plurality of bit lines BL, a plurality of input lines IL, and a plurality of output lines OL. The gate of the access transistor 311 may be electrically connected to any one of the plurality of word lines WL, the source thereof may be electrically connected to any one of the plurality of bit lines BL, and the drain thereof may be connected to the gate of the ferroelectric field effect transistor 312. Further, the source of the ferroelectric field effect transistor 312 may be electrically connected to an input line of any one of the plurality of input lines IL, and a drain thereof may be electrically connected to an output line of any one of the plurality of output lines OL.

During the learning operation of the neural network apparatus 300, the access transistor 311 is individually turned on through individual word lines WL, and a program pulse may be applied to the gate of the ferroelectric field effect transistor 312 through the bit lines BL. A signal of the training data may be applied through the input line IL. Through this process, weights may be stored in each ferroelectric field effect transistor 312.

During the inference operation of the neural network apparatus 300, all access transistors 311 may be turned on through the entire word lines WL, and a read voltage Vread may be applied through the bit lines BL. Then, the current from synapse elements 310 connected in parallel to the output line OL is added to and flows in each output line OL. An output circuit is connected to the plurality of output lines OL to convert a current flowing through each output line OL into a digital signal.

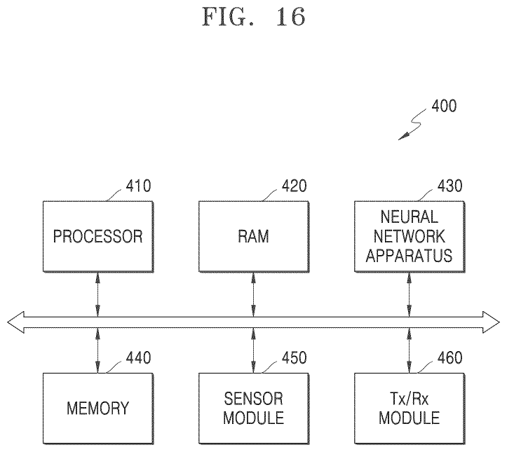

FIG. 16 is a schematic block diagram showing an example configuration of an electronic apparatus including a neural network apparatus. Referring to FIG. 16, the electronic apparatus 400 may analyze input data in real time based on a neural network to extract valid information, determine a situation based on the extracted information, or control configurations of a device equipped with the electronic apparatus 400. For example, the electronic apparatus 400 may be applied to a robot device such as a drone, an advanced driver assistance system (ADAS), or the like, a smart TV, a smartphone, a medical device, a mobile device, an image display device, a measurement device, and an IoT device, and the like, and may be mounted on at least one of various types of devices.

The electronic apparatus 400 may include a processor 410, a random access memory (RAM) 420, a neural network apparatus 430, a memory 440, a sensor module 450, and a communication module 460. The electronic apparatus 400 may further include an input/output module, a security module, a power control device, and the like. Some of the hardware components of the electronic apparatus 400 may be mounted on at least one semiconductor chip.

The processor 410 controls the overall operation of the electronic apparatus 400. The processor 410 may include one processor core or a plurality of processor cores (e.g., Multi-Core).

The processor 410 may process or execute programs and/or data stored in the memory 440. In some embodiments, the processor 410 may control the function of the neural network apparatus 430 by executing programs stored in the memory 440. The processor 410 may be implemented as a central processing unit (CPU), a graphics processing unit (GPU), an application processor (AP), or the like.

The RAM 420 may temporarily store programs, data, or instructions. For example, programs and/or data stored in the memory 440 may be temporarily stored in the RAM 420 according to the control or boot code of the processor 410. The RAM 420 may be implemented as a memory such as dynamic RAM (DRAM), static RAM (SRAM), or the like.

The neural network apparatus 430 may perform an operation of the neural network based on the received input data and generate an information signal based on the execution result. The neural network may include, but is not limited to, convolutional neural network (CNN), recurrent neural network (RNN), feedforward neural network (FNN), long short-term memory (LSTM), stacked neural network (SNN), state-space dynamic neural network (SSDNN), deep belief networks (DBN), restricted Boltzmann machine (RBM), and/or the like. The neural network apparatus 430 may be a hardware accelerator itself dedicated to a neural network or an apparatus including the same. The neural network apparatus 430 may perform a read or write operation as well as an operation of the neural network. The neural network apparatus 430 may correspond to and/or include the neural network apparatus 300 according to the at least one embodiment illustrated in FIG. 15; one of the ferroelectric field effect transistors 100, 100a, 100b, 100c, and 100d described in FIGS. 1 to 9; and/or a memory cell string of a memory device described in FIGS. 10 to 14.

The information signal may include one of various types of recognition signals such as a voice recognition signal, an object recognition signal, an image recognition signal, a biometric information recognition signal, and/or the like. For example, the neural network apparatus 430 may receive frame data included in the video stream as input data and generate, from frame data, a recognition signal for an object included in an image represented by the frame data. However, the neural network apparatus is not limited thereto, and the neural network apparatus 430 may receive various types of input data and generate a recognition signal according to the input data according to the type or function of the device on which the electronic apparatus 400 is mounted.

The neural network apparatus 430 may perform, for example, machine learning model such as linear regression, logistic regression, statistical clustering, Bayesian classification, decision trees, principal component analysis, expert system, and/or the like; and/or machine learning model of ensemble techniques, etc., such as random forest. The machine learning model may be used to provide various services such as, for example, image classification service, user authentication service based on biometric information or biometric data, advanced driver assistance system (ADAS), voice assistant service, automatic speech recognition (ASR) service, and the like.

The memory 440 is a storage place for storing data and may store an operating system (OS), various programs, and various pieces of data. In at least one embodiment, the memory 440 may store intermediate results generated during the operation of the neural network apparatus 430.

The memory 440 may be a dynamic random access memory (DRAM), but is not limited thereto. The memory 440 may include at least one of a volatile memory and a nonvolatile memory.

The nonvolatile memory includes read-only memory (ROM), programmable ROM (PROM), electrically programmable ROM (EPROM), electrically erasable and programmable ROM (EEPROM), flash memory, phase-change ROM (PROM), magnetic ROM (MROM), resistive ROM (RROM), ferroelectric ROM (FROM), and/or the like. The volatile memory includes dynamic RAM (DRAM), static RAM (SRAM), synchronous DRAM (SDRAM), phase-change RAM (PRAM), magnetic RAM (MRAM), resistive RAM (RRAM), ferroelectric RAM (FeRAM), and/or the like. In at least one embodiment, the memory 440 may include at least one of a hard disk drive (HDD), a solid state drive (SSD), a compact flash (CF), a secure digital (SD), a micro secure digital (Micro-SD), a mini secure digital (Mini-SD), a memory stick, and/or the like.

The sensor module 450 may collect information around a device on which the electronic apparatus 400 is mounted. The sensor module 450 may sense or receive a signal (e.g., an image signal, a voice signal, a magnetic signal, a bio signal, a touch signal, etc.) from outside of the electronic apparatus 400 and convert the sensed or received signal into data. To this end, the sensor module 450 may include at least one of various types of sensing devices such as a sensing device, for example, a microphone, an imaging device, an image sensor, a light detection and ranging (LIDAR) sensor, an ultrasonic sensor, an infrared sensor, a biosensor, and a touch sensor.

The sensor module 450 may provide the converted data to the neural network apparatus 430 as input data. For example, the sensor module 450 may include an image sensor, generate a video stream by photographing an external environment of the electronic device 400, and sequentially provide the continuous data frame of the video stream to the neural network apparatus 430 as input data. However, embodiments are not limited thereto, and the sensor module 450 may provide various types of data to the neural network apparatus 430.

The communication module 460 may include various wired or wireless interfaces capable of communicating with an external device. For example, the communication module 460 may include a wired local area network (LAN), a wireless local area network (WLAN) such as a wireless fidelity (Wi-Fi), a wireless personal area network (WPAN) such as Bluetooth, a wireless universal serial bus (USB), Zigbee, near field communication (NFC), radio-frequency identification (RFID), power line communication (PLC), and a communication interface capable of connecting to a mobile cellular network, such as 3rd generation (3G), 4th generation (4G), 5th generation (5G), long term evolution (LTE), and/or the like.

The ferroelectric field effect transistor, memory device, and neural network device including the ferroelectric gate-interposed layer described above are described with reference to the example embodiments illustrated in the drawings, but it should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A ferroelectric field effect transistor comprising:
a source region;
a drain region;
a channel between the source region and the drain region;
a gate electrode over the channel;
a ferroelectric layer between the channel and the gate electrode and including a ferroelectric material including an oxide of a first element; and
a gate-interposed layer between the ferroelectric layer and the gate electrode and including a paraelectric material including an oxide of a second element different from the first element
wherein the gate-interposed layer comprises a first interposed region adjacent to the ferroelectric layer; and a second interposed region adjacent to the gate electrode, and
the first interposed region includes a mixture of the first element and the second element, and an average ratio of the first element in the first interposed region is greater than an average ratio of the first element in the ferroelectric layer.

2. The ferroelectric field effect transistor of claim 1, wherein the paraelectric material has a dielectric constant of about 8 or less.

3. The ferroelectric field effect transistor of claim 1, wherein the paraelectric material includes at least one of SiO₂, Al₂O₃, SiAlOₓ, or Si₃N₄.

4. The ferroelectric field effect transistor of claim 1, wherein the first interposed region is configured as a charge trap.

5. The ferroelectric field effect transistor of claim 1, wherein a content of the first element in the ferroelectric layer and the first interposed region exhibits a first peak in the ferroelectric layer and a second peak in the first interposed region which decreases with proximity towards the second interposed region.

6. The ferroelectric field effect transistor of claim 5, wherein a magnitude of the second peak is greater than a magnitude of the first peak.

7. The ferroelectric field effect transistor of claim 5, wherein a magnitude of the second peak is about 105% or more of a magnitude of the first peak.

8. The ferroelectric field effect transistor of claim 1, wherein the first element comprises at least one of hafnium (Hf) or zirconium (Zr).

9. The ferroelectric field effect transistor of claim 1, wherein the first element is hafnium (Hf), and a difference between an elemental content of hafnium in the first interposed region and an elemental content of hafnium in the ferroelectric layer is greater than 0 at % and less than or equal to about 25 at %.

10. The ferroelectric field effect transistor of claim 1, wherein the first element is hafnium (Hf), and an elemental content of hafnium in the first interposed region is within a range of about 105% to about 130% of an elemental content of hafnium in the ferroelectric layer.

11. The ferroelectric field effect transistor of claim 1, wherein a content of the second element in the first interposed region gradually increases, and a content of the second element in the second interposed region exhibits a peak in the second interposed region.

12. The ferroelectric field effect transistor of claim 1, wherein a thickness of the first interposed region is within a range of about 1 nm to about 7 nm, a thickness of the second interposed region is about 3 nm or more, and a total thickness of the gate-interposed layer is within a range of about 4 nm or more about 10 nm or less.

13. The ferroelectric field effect transistor of claim 1, wherein
the ferroelectric layer comprises a plurality of first material layers and at least one second material layer between two adjacent first material layers, of the plurality of first material layers, facing each other, and
the first material layer comprises the ferroelectric material, and the second material layer comprises a paraelectric material.

14. The ferroelectric field effect transistor of claim 13, wherein a thickness of a first material layer, of the plurality of first material layers, is within a range of about 5 nm to about 10 nm, and a thickness of the second material layer is within a range of about 0.1 nm to about 1 nm.

15. The ferroelectric field effect transistor of claim 13, wherein the paraelectric material of the second material layer comprises at least one of Al₂O₃, SiO₂, La₂O₃, or Y₂O₃.

16. The ferroelectric field effect transistor of claim 1, further comprising:
an interfacial layer between the channel and the ferroelectric layer, the interfacial layer comprising an oxide of a semiconductor material or an oxynitride of a semiconductor material.

17. The ferroelectric field effect transistor of claim 16, further comprising:
a diffusion barrier layer between the ferroelectric layer and the interfacial layer, the diffusion barrier layer comprising at least one of SiN, AlN, or TaN.

18. The ferroelectric field effect transistor of claim 17, wherein a thickness of the diffusion barrier layer is within a range of about 1 nm to about 2 nm.

19. A memory device comprising:
a plurality of gate electrodes and a plurality of spacers, alternating in a first direction;
a channel extending in the first direction and spaced apart from the plurality of gate electrodes and the plurality of spacers in a second direction perpendicular to the first direction;
a ferroelectric layer extending in the first direction and between the channel and the plurality of gate electrodes, the ferroelectric layer including a ferroelectric material including an oxide of a first element; and
a gate-interposed layer extending in the first direction and between the ferroelectric layer and the plurality of gate electrodes, the gate-interposed layer including a paraelectric material including an oxide of a second element different from the first element,
wherein the gate-interposed layer comprises a first interposed region adjacent to the ferroelectric layer; and a second interposed region adjacent to the gate electrodes,
the first interposed region comprises a mixture of the first element and the second element, and an average ratio of the first element in the first interposed region is greater than an average ratio of the first element in the ferroelectric layer.

20. A neural network apparatus comprising:
an array of a plurality of synapse elements,
wherein each of the synapse elements includes an access transistor and a ferroelectric field effect transistor, and
the ferroelectric field effect transistor comprises
a source region,
a drain region,
a channel between the source region and the drain region,
a gate electrode over the channel,
a ferroelectric layer between on the channel and the gate electrode and including
a ferroelectric material including an oxide of a first element, and
a gate-interposed layer between the ferroelectric layer and the gate electrode and including a paraelectric material including an oxide of a second element different from the first element,
wherein the gate-interposed layer comprises a first interposed region adjacent to the ferroelectric layer; and a second interposed region adjacent to the gate electrode,
the first interposed region comprises a mixture of the first element and the second element, and an average ratio of the first element in the first interposed region is greater than an average ratio of the first element in the ferroelectric layer.
